(19) United States
(12) Patent Application Publication
(10) Pub. No.: US 2017/0373032 A1
(43) Pub. Date: Dec. 28, 2017

(54) REDISTRIBUTION LAYER (RDL) FAN-OUT WAFER LEVEL PACKAGING (FOWLP) STRUCTURE

(71) Applicant: QUALCOMM Incorporated, San Diego, CA (US)

(72) Inventors: Jihoon OH, San Diego, CA (US); Ruey Kae ZANG, San Diego, CA (US); Lizabeth Ann KESER, San Diego, CA (US); Reynante Tamunan ALVARADO, San Diego, CA (US); Haiyong XU, San Diego, CA (US); Yue LI, San Diego, CA (US); Steve BEZUK, Poway, CA (US)

(21) Appl. No.: 15/192,825

(22) Filed: Jun. 24, 2016

(51) Int. Cl. H01L 23/00; H01L 23/31; H01L 23/498

(52) U.S. Cl. CPC H01L 24/14; H01L 23/49838; H01L 23/49822; H01L 23/3114; H01L 2924/1433; H01L 2924/1431; H01L 2924/141; H01L 2224/1412; H01L 2224/13155; H01L 2224/13147; H01L 2224/13144; H01L 2224/13139; H01L 2224/13124; H01L 2224/13116; H01L 2224/13113; H01L 2224/13111; H01L 2224/13024; H01L 2224/02379; H01L 2224/14177; H01L 2224/1416; H01L 2224/02373; H01L 2224/02372; H01L 2224/02331; H01L 2924/14335; H01L 2924/19011; H01L 2924/2064; H01L 2924/19042

(57) ABSTRACT

Disclosed is a fan-out wafer level packaging (FOWLP) apparatus includes a semiconductor die having at least one input/output (I/O) connection, a first plurality of package balls having a first package ball layout, a first conductive layer forming a first redistribution layer (RDL) and configured to electrically couple to the first plurality of package balls, and a second conductive layer forming a second RDL and including at least one conductive pillar configured to electrically couple the at least one I/O connection of the semiconductor die to the first conductive layer, wherein the second conductive layer enables the semiconductor die to be electrically coupled to a second plurality of package balls having a second package ball layout without a change in position of the at least one I/O connection of the semiconductor die.

### INTRODUCTION

Embodiments relate to a redistribution layer (RDL) fan-out wafer level packaging (FOWLP) structure.

FOWLP is an enhancement of standard wafer-level packaging (WLP) developed to provide a solution for semiconductor devices requiring a higher integration level and a greater number of external contacts. It also provides a smaller package footprint with higher input/output (I/O), along with better thermal and electrical performance than standard WLP.

Specifically, in conventional WLP (also referred to as “fan-in” WLP), I/O terminals can only be located within the footprint of the semiconductor device on the wafer. Using this method, there is a limit to the number of I/O connections that a given semiconductor device can have. In contrast, FOWLP takes individual semiconductor devices and embeds them in a low cost material, such as epoxy mold compound (EMC), with space allocated between each semiconductor device for additional I/O connection points. In this way, I/O connections for a given semiconductor device can “fan-out” from the footprint of the semiconductor device on the wafer.

This “fan out” occurs in the RDL of a wafer. RDLs are formed on the wafers using particle vapor deposition (PVD) and subsequent electroplating/patterning to re-route I/O connections of a semiconductor device to the package balls (a.k.a. “solder balls,” “solder bumps,” or “bumps”).

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In an embodiment, a fan-out wafer level packaging (FOWLP) apparatus includes a semiconductor die having at least one input/output (I/O) connection, a first plurality of package balls having a first package ball layout, a first conductive layer forming a first redistribution layer (RDL) and configured to electrically couple to the first plurality of package balls, and a second conductive layer forming a second RDL and including at least one conductive pillar configured to electrically couple the at least one I/O connection of the semiconductor die to the first conductive layer, wherein the second conductive layer enables the semiconductor die to be electrically coupled to a second plurality of package balls having a second package ball layout without a change in position of the at least one I/O connection of the semiconductor die.

In an embodiment, a method of providing a FOWLP apparatus includes providing a semiconductor die having at least one I/O connection, providing a first plurality of package balls having a first package ball layout, forming a first RDL comprising a first conductive layer electrically coupled to the first plurality of package balls, and forming a second RDL comprising a second conductive layer including at least one conductive pillar electrically coupling the at least one I/O connection of the semiconductor die to the first conductive layer, wherein the second conductive layer enables the semiconductor die to be electrically coupled to a second plurality of package balls having a second package ball layout without a change in position of the at least one I/O connection of the semiconductor die.

In an embodiment, a FOWLP apparatus includes a semiconductor die having at least one I/O connection, a first plurality of package balls having a first package ball layout, a first conductive means forming a first RDL and configured to electrically couple to the first plurality of package balls, and a second conductive means forming a second RDL and including at least one conductive pillar configured to electrically couple the at least one I/O connection of the semiconductor die to the first conductive means, wherein the second conductive means enables the semiconductor die to be electrically coupled to a second plurality of package balls having a second package ball layout without a change in position of the at least one I/O connection of the semiconductor die.

In an embodiment, a non-transitory computer-readable medium storing computer executable code, including code to cause a machine to provide a semiconductor die having at least one I/O connection, cause a machine to provide a first plurality of package balls having a first package ball layout, cause a machine to form a first RDL comprising a first conductive layer configured to electrically couple to the first plurality of package balls, and cause a machine to form a second RDL comprising a second conductive layer including at least one conductive pillar configured to electrically couple the at least one I/O connection of the semiconductor die to the first conductive layer, wherein the second conductive layer enables the semiconductor die to be electrically coupled to a second plurality of package balls having a second package ball layout without a change in position of the at least one I/O connection of the semiconductor die.

Other objects and advantages associated with the aspects and embodiments disclosed herein will be apparent to those skilled in the art based on the accompanying drawings and detailed description.

### BRIEF DESCRIPTION OF THE DRAWINGS

A more complete appreciation of embodiments of the disclosure will be readily obtained as the same becomes better understood by reference to the following detailed description when considered in connection with the accompanying drawings which are presented solely for illustration and not limitation of the disclosure, and in which:

FIG. 1A illustrates an exemplary conventional fan-out wafer level packaging (FOWLP) structure.

FIG. 1B illustrates another exemplary conventional FOWLP structure.

FIG. 2 illustrates an exemplary FOWLP structure according to at least one aspect of the disclosure.

FIG. 3A illustrates an exemplary FOWLP structure according to at least one aspect of the disclosure.

FIG. 3B illustrates an exemplary FOWLP structure according to at least one aspect of the disclosure.

FIG. 4 illustrates two exemplary 1.5 RDL FOWLP structures according to at least one aspect of the disclosure.

FIGS. 5A-F illustrate an exemplary method of fabricating a 1.5 FOWLP structure according to at least one aspect of the disclosure.

FIG. 6 illustrates a top view of an exemplary 1.5 RDL FOWLP structure according to at least one aspect of the disclosure

FIG. 7 illustrates a three-dimensional diagram of an exemplary 1.5 RDL FOWLP structure according to at least one aspect of the disclosure

FIG. 8A illustrates an exemplary FOWLP structure for a power management integrated circuit (PMIC) application.

FIG. 8B illustrates an exemplary FOWLP structure for the PMIC application illustrated in FIG. 8A according to at least one aspect of the disclosure.

FIG. 9 illustrates how a 1.5 RDL FOWLP structure can be used in a radio frequency (RF) inductor application according to at least one aspect of the disclosure.

FIG. 10 illustrates a three-dimensional diagram of an exemplary 1.5 RDL FOWLP structure used in a toroid inductor according to at least one aspect of the disclosure

FIG. 11 illustrates an exemplary flow for providing a 1.5 RDL FOWLP apparatus according to at least one aspect of the disclosure.

### DETAILED DESCRIPTION

Disclosed is a fan-out wafer level packaging (FOWLP) apparatus that includes a semiconductor die having at least one input/output (I/O) connection, a first plurality of package balls having a first package ball layout, a first conductive layer forming a first redistribution layer (RDL) and configured to electrically couple to the first plurality of package balls, and a second conductive layer forming a second RDL and including at least one conductive pillar configured to electrically couple the at least one I/O connection of the semiconductor die to the first conductive layer, wherein the second conductive layer enables the semiconductor die to be electrically coupled to a second plurality of package balls having a second package ball layout without a change in position of the at least one I/O connection of the semiconductor die.

These and other aspects of the disclosure are disclosed in the following description and related drawings directed to specific embodiments of the disclosure. Alternate embodiments may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any embodiment described herein as “exemplary” and/or “example” is not necessarily to be construed as preferred or advantageous over other embodiments. Likewise, the term “embodiments of the disclosure” does not require that all embodiments of the disclosure include the discussed feature, advantage or mode of operation.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

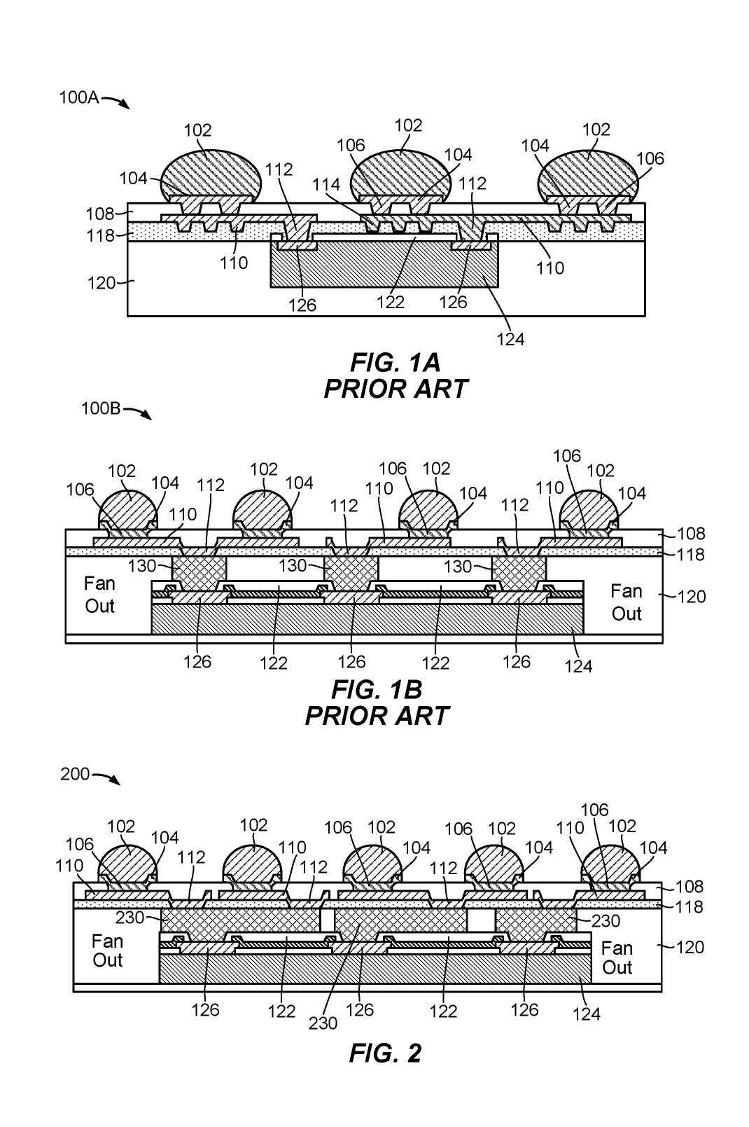

FIG. 1A illustrates an exemplary conventional fan-out wafer level packaging (FOWLP) structure 100A. The FOWLP structure 100A includes insulating layers 108 and 118, conductive layers 104 and 110, and package balls 102 (also referred to as “bumps”). In the example of FIG. 1A, the conductive layer 104 forms a plurality of vias 106 through the insulating layer 108. Each via 106 formed by the conductive layer 104 connects the conductive layer 104 to the conductive layer 110. In the example of FIG. 1A, the conductive layer 110 forms a number of grooves 114, or micro vias, in the insulating layer 118. The depth of the grooves 114 is less than the thickness of insulating layer 118. The conductive layer 110 additionally forms a plurality of vias 112 through the insulating layer 118. An encapsulant 120, or molding compound, is deposited over a semiconductor die 124, which includes a conductive layer 126 (e.g., die pads or vias) and an insulating layer 122. The conductive layer 126 forms the input/output (I/O) connections of the semiconductor die 124. The vias 112 formed by the conductive layer 110 connect the conductive layer 110 to the conductive layer 126 of the semiconductor die 124.

The conductive layer 110 (including vias 112) makes up the redistribution layer (RDL) of the FOWLP structure 100A. The conductive layer 110 re-routes the I/O connections formed by the conductive layer 126 of the semiconductor die 124 to the package balls 102. More specifically, because the conductive layer 110 “redistributes” the I/O connections of the semiconductor die 124 to the package balls 102, there is no need for each 110 connection of the semiconductor die 124 to align vertically with a package ball 102 and connect to the package ball 102 over a via 106 of the conductive layer 104.

The insulating layers 122, 118, and 108 may be one or more layers of silicon dioxide (SiO2), silicon nitride (Si3N4), silicon oxynitride (SiON), tantalum pentoxide (Ta2O5), aluminum oxide (Al2O3), hafnium oxide (HfO2), benzocyclobutene (BCB), polyimide (PI), polybenzoxazoles (PBO), or other material having similar insulating and structural properties, as is known in the art. The conductive layers 104, 110, and 126 may be one or more layers of aluminum (Al), copper (Cu), tin (Sn), nickel (Ni), gold (Au), silver (Ag), or other suitable electrically conductive material, as is known in the art. The package balls 102 may be Al, Cu, Sn, Ni, Au, Ag, lead (Pb), bismuth (Bi), solder, or combinations thereof, with an optional flux solution, as is known in the art. The encapsulant 120 may be a polymer composite material, such as epoxy resin with filler, epoxy acrylate with filler, or polymer with proper filler and is non-conductive, provides physical support, and environmentally protects the semiconductor die 124 from external elements and contaminants, as is known in the art. The semiconductor die 124 may be an integrated circuit (IC), a digital signal processor (DSP), an application specific integrated circuit (ASIC), a field programmable gate array (FPGA), or other programmable logic device.

FIG. 1B illustrates another exemplary conventional FOWLP structure 100B. Like the FOWLP structure 100A, the FOWLP structure 100B includes insulating layers 108 and 118, conductive layers 104 and 110, and package balls 102. The conductive layer 104 forms a plurality of vias 106 through the insulating layer 108. Each via 106 formed by the conductive layer 104 connects the conductive layer 104 to the conductive layer 110. The conductive layer 110 forms a plurality of vias 112 through the insulating layer 118. Additionally, an encapsulant 120 is deposited over a semiconductor die 124, which includes a conductive layer 126 and an insulating layer 122.

Unlike the FOWLP structure 100A, however, the FOWLP structure 100B includes a plurality of conductive pillars 130. In the FOWLP structure 100B, both the conductive layer 110 (including vias 112) and the conductive pillars 130 are RDLs. Each conductive pillar 130 of the FOWLP structure 100B connects a via 112 of the conductive layer 110 to an I/O connection formed by the conductive layer 126 of the semiconductor die 124. The conductive pillars 130 have a width-to-height ratio of less than one, meaning that the width of a conductive pillar 130 is less than the height of the conductive pillar 130. The height of the conductive pillars 130 may be approximately 6 μm. The conductive pillars 130 can be one or more layers of Al, Cu, Sn, Ni, Au, Ag, or other suitable electrically conductive material, as is known in the art.

An issue with existing FOWLP structures, such as FOWLP structure 100B, is that the conductive pillars 130 only provide vertical connectivity between vias 112 of the conductive layer 110 and the I/O connections formed by the conductive layer 126 of the semiconductor die 124. As such, a change in the layout of the package balls 102 (e.g., where the semiconductor die 124 is being laid out on a different ball map) necessitates a change in the locations of the I/O connections formed by the conductive layer 126 of the semiconductor die 124. More specifically, because the conductive pillars 130 only provide vertical connectivity between vias 112 and the I/O connections formed by the conductive layer 126, when the layout of the package balls 102, and thus the layout of the conductive layer 110 (including vias 112), changes, the I/O connections formed by the conductive layer 126 may no longer be vertically aligned with the vias 112 in the conductive layer 110. As such, the layout of the I/O connections formed by the conductive layer 126 will be changed to match the new layout of the package balls 102.

Accordingly, the present disclosure provides an RDL of conductive pillars to redistribute the I/O connections formed by the conductive layers 126 of the semiconductor die 124 to align with various package ball layout patterns and the corresponding conductive layer 110.

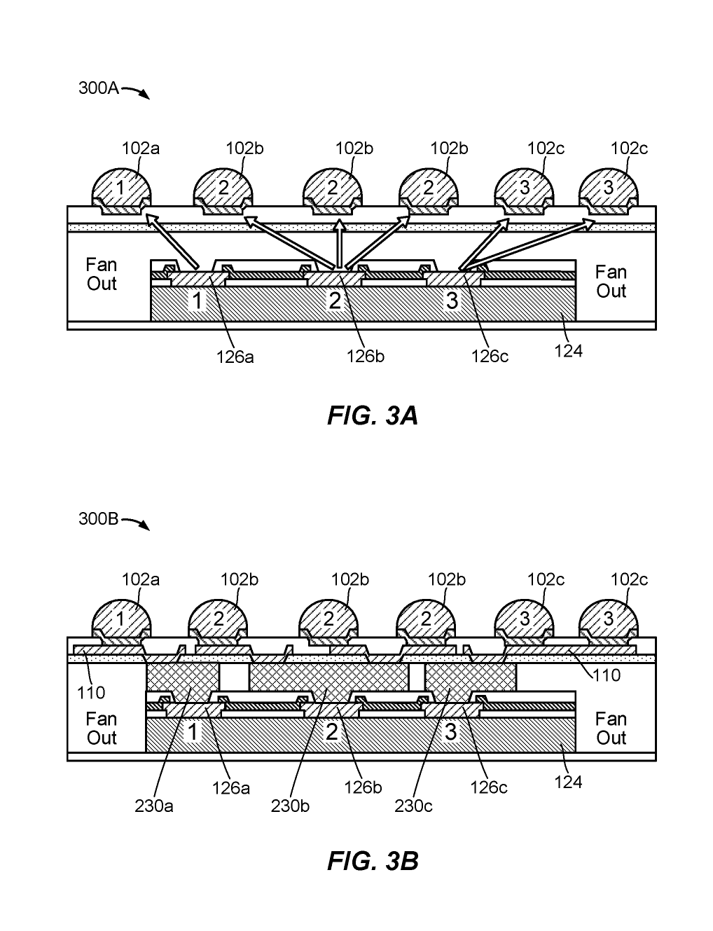

FIG. 2 illustrates an exemplary FOWLP structure 200 according to at least one aspect of the disclosure. Like the FOWLP structures 100A and 100B, the FOWLP structure 200 includes insulating layers 108 and 118, conductive layers 104 and 110, and package balls 102. The conductive layer 104 forms a plurality of vias 106 through the insulating layer 108. Each via 106 formed by the conductive layer 104 connects the conductive layer 104 to the conductive layer 110. The conductive layer 110 forms a plurality of vias 112 through the insulating layer 118. Additionally, an encapsulant 120 is deposited over a semiconductor die 124, which includes a conductive layer 126 and an insulating layer 122.

The FOWLP structure 200 also includes a plurality of conductive pillars 230. In the FOWLP structure 200, both the conductive layer 110 (including vias 112) and the conductive pillars 230 are RDLs. For convenience, the conductive layer 110 (and vias 112) may be referred to herein as the “first” RDL and the conductive pillars 230 may be referred to as the “second” RDL.

Similar to the conductive pillars 130 of the FOWLP structure 100B, each conductive pillar 230 connects a via 112 of the conductive layer 110 to an I/O connection formed by the conductive layer 126 of the semiconductor die 124. Unlike the conductive pillars 130 in the FOWLP structure 100B, however, the conductive pillars 230 have a width-to-height ratio greater than one (e.g., 1.5), meaning that the width of a conductive pillar 230 is greater than the height of the conductive pillar 230. For example, the width of a conductive pillar 230 may be 1.5 times the height of the conductive pillar 230. The height of the conductive pillars 230 may be approximately 30 μm, that is, within some tolerance threshold of 30 μm. Similar to the conductive pillars 130, the conductive pillars 230 may be one or more layers of Al, Cu, Sn, Ni, Au, Ag, or other suitable electrically conductive material.

As will be described further herein, the greater width-to-height ratio of the conductive pillars 230 allows for redistribution of the I/O connections formed by the conductive layer 126 of the semiconductor die 124 to align with a given package ball layout and the conductive layer 110 (including vias 112) corresponding to that package ball layout without having to redesign the layout of the I/O connections formed by the conductive layers 126.

For convenience, an RDL of a FOWLP structure (e.g., FOWLP structure 200) that includes conductive pillars (e.g., conductive pillars 230) as described herein is referred to as a “1.5 RDL FOWLP structure,” where “1.5” refers to the width-to-height ratio of the conductive pillars. However, as will be appreciated, the disclosure is not limited to a width-to-height ratio of 1.5, but rather, is applicable to any width-to-height ratio greater than one that allows for redistribution of the I/O connections of a semiconductor die to align with various package ball layout patterns without having to redesign the layout of the I/O connections.

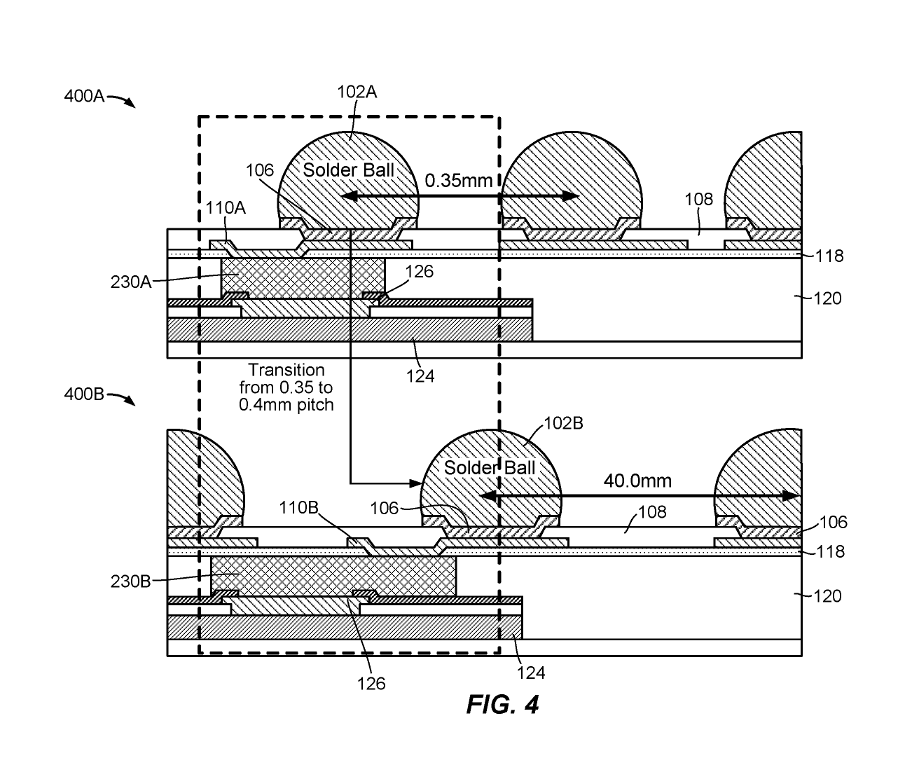

FIG. 3A illustrates an exemplary FOWLP structure 300A according to at least one aspect of the disclosure. For simplicity, FIG. 3A only shows reference numbers for package balls 102, semiconductor die 124, and the conductive layer 126. However, it will be appreciated that the remaining layers of the FOWLP structure 300A correspond to the insulating layers 108, 118, and 122, the conductive layers 104 and 110, the vias 106 and 112, and the encapsulant 120 of the FOWLP structure 200 in FIG. 2.

In FIG. 3A, the arrows illustrate to which package ball(s) 102 a particular I/O connection formed by the conductive layer 126 of the semiconductor die 124 needs to connect. Specifically, in the example of FIG. 3A, the I/O connection formed by the conductive layer 126a needs to connect to the package ball 102a, the I/O connection formed by the conductive layer 126b needs to connect to the package balls 102b, and the I/O connection formed by the conductive layer 126c needs to connect to the package balls 102c. As will be appreciated, vertical conductive pillars with a width-to-height ratio of less than one, such as conductive pillars 130 in FIG. 1B, will not be able to provide a connection between the I/O connections formed by conductive layers 126a, 126b, and 126c and the package balls 102a, 102b, and 102c, respectively, without a redesign of the layout of the I/O connections formed by the conductive layers 126a, 126b, and 126c.

FIG. 3B illustrates an exemplary FOWLP structure 300B according to at least one aspect of the disclosure. In FIG. 3B, the first RDL (e.g., conductive layer 110) and the conducive pillars 230 have been added to the FOWLP structure 300A of FIG. 3A. For simplicity, FIG. 3B only shows reference numbers for package balls 102, conductive layer 110, semiconductor die 124, conductive layer 126, and conductive pillars 230. However, it will be appreciated that the remaining layers of the FOWLP structure 300B correspond to the insulating layers 108, 118, and 122, the conductive layer 104, the vias 106 and 112, and the encapsulant 120 of the FOWLP structure 200 in FIG. 2.

In FIG. 3B, the package balls 102 are shown connected to the conductive layer 110. In addition, FIG. 3B shows how the conductive pillars 230a-c connect the I/O connections formed by the conductive layers 126a-c to the package balls 102a-c. Specifically, the conductive pillar 230a connects the I/O connection formed by the conductive layer 126a to the package ball 102a, the conductive pillar 230b connects the I/O connection formed by the conductive layer 126b to the package balls 102b, and the conductive pillar 230c connects the I/O connection formed by the conductive layer 126c to the package balls 102c.

Thus, as shown in FIGS. 3A and 3B, the greater width-to-height ratio of the conductive pillars 230 allows the I/O connections formed by the conductive layers 126 of the semiconductor die 124 to align with the layout of the package balls 102 and the corresponding conductive layer 110 without having to redesign the layout of the I/O connections formed by the conductive layer 126 as would be done if using the conductive pillars 130 of FIG. 1B.

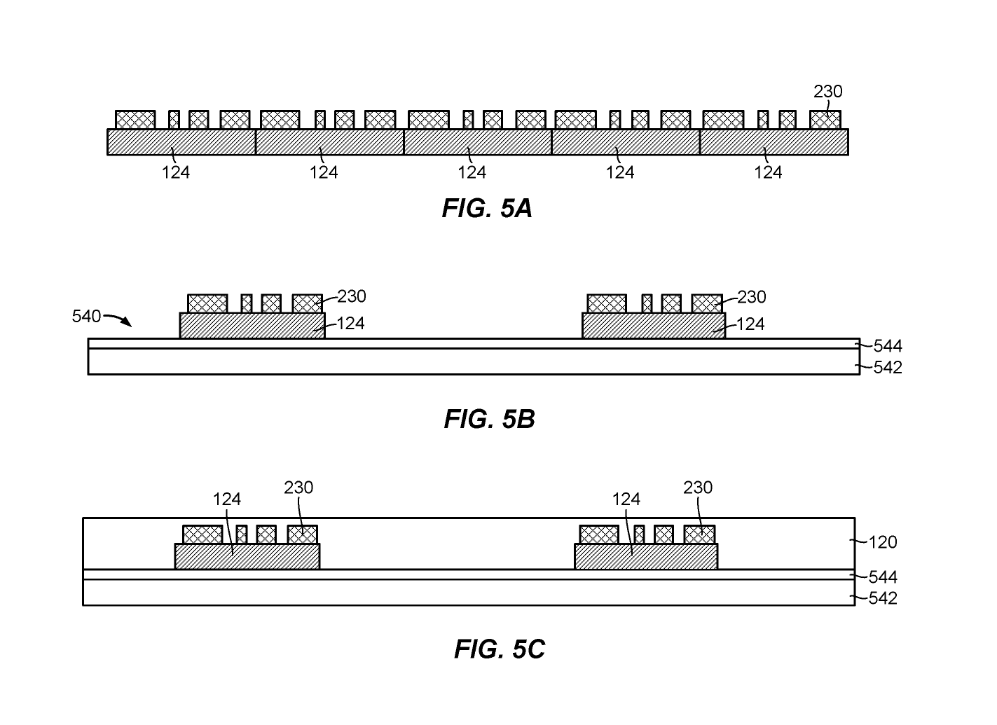

An example of this aspect is shown in greater detail in FIG. 4. FIG. 4 illustrates two exemplary 1.5 RDL FOWLP structures 400A and 400B according to at least one aspect of the disclosure. The 1.5 RDL FOWLP structure 400A utilizes a 0.35 mm package ball pitch with a corresponding conductive layer 110A (i.e., the first RDL), and the 1.5 RDL FOWLP structure 400B utilizes a 0.40 mm package ball pitch with a corresponding conductive layer 110B. In the 1.5 RDL FOWLP structure 400A, the I/O connection formed by the conductive layer 126 of semiconductor die 124 connects to package ball 102A (of the 0.35 mm package ball layout) via conductive pillar 230A. In the 1.5 RDL FOWLP structure 400B, however, the I/O connection formed by the conductive layer 126 of semiconductor die 124 connects to package ball 102B (of the 0.40 mm package ball layout) via conductive pillar 230B.

As shown in FIG. 4, despite the difference in package ball layout between 1.5 RDL FOWLP structure 400A and 1.5 RDL FOWLP structure 400B, as well as the difference between their corresponding conductive layers 110A and 110B, respectively, there is no change to the location of the I/O connections formed by the conductive layer 126 of the semiconductor die 124. Rather, only the size and position of the conductive pillar 230A/B changes. Conventionally, the location of the I/O connections formed by the conductive layer 126 would have to change due to the change in the package ball layout.

Table 1 illustrates the heights (or thicknesses) of various components of a 1.5 FOWLP structure according to at least one aspect of the disclosure.

TABLE 1

| Description | 1.5 RDL FOWLP |
|---|---|
| Second Insulating/Dielectric Layer Thickness | 9.3 μm |
| First RDL (CuPPI) Thickness | 8.0 μm |
| First Insulating/Dielectric Layer Thickness | 8.8 μm |
| Conductive Pillar Thickness (Second RDL) | 20 μm-150 μm |
| Semiconductor Die Thickness | 465 μm |

With reference to FIG. 2, the “First RDL Thickness” in TABLE 1 would correspond to the height of the conductive layer 110, and the “Conductive Pillar Thickness” would correspond to the height of the conductive pillars 230. The “Semiconductor Die Thickness” would correspond to the height of the semiconductor die 124.

Table 2 illustrates various exemplary design rules for a 1.5 FOWLP structure according to at least one aspect of the disclosure. In the table below, the 0.5 RDL layer is a copper pillar layer that is used for RDL connections, and is routed inside the silicon area. It is referred to as a “0.5 RDL Layer” because it does not extend into the fan out area.

TABLE 2

| | Design Item | 1.5 RDL FOWLP |
|---|---|---|
| 0.5 RDL Layer | Conductive Pillar Diameter | Minimum 35 μm |
| | | (Passivation Opening + |
| | | 15 μm) |
| | Conductive Pillar Pitch | 50 μm (minimum space |
| | | between conductive pillar: |
| | | 15 μm) |
| | +RDL Trace Width/Space | 35 μm/15 μm |
| FOWLP Layers | First RDL Line Width/ | Minimum 15 μm/15 μm |
| | Space | |
| | First RDL to Package Edge | Minimum 70 μm |
| | Via Size | Minimum 21 μm |
| | Via Size | Typical Design Rules |
| | Under Bump Metallurgy | Typical Design Rules |
| | (UBM) Size | |

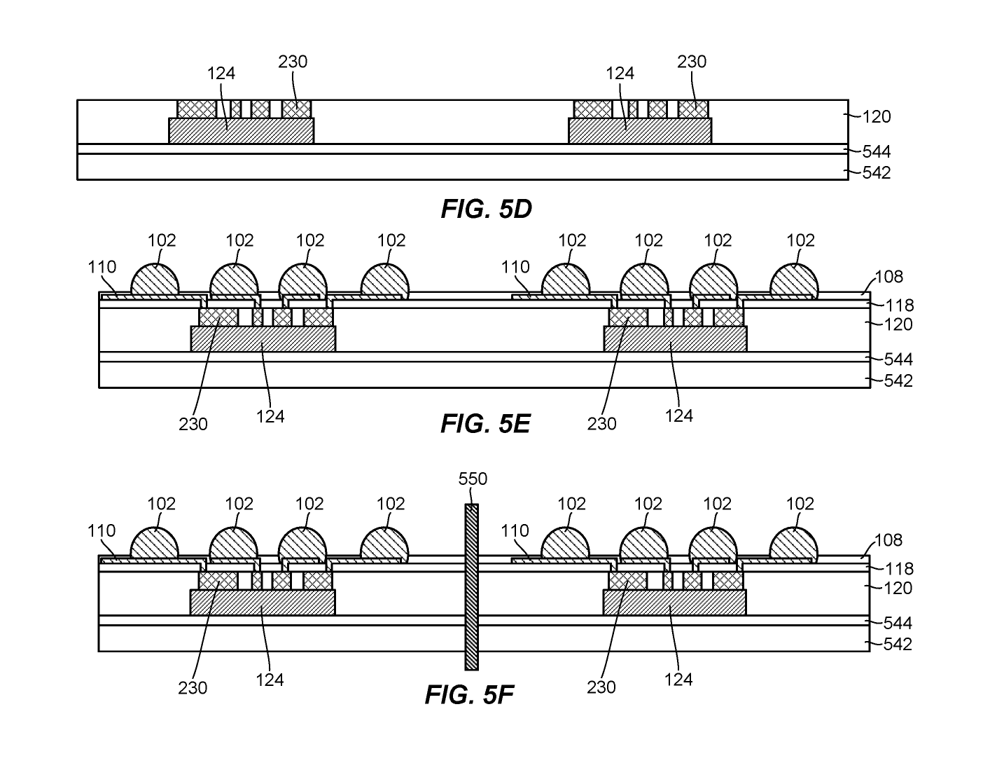

FIGS. 5A-F illustrate an exemplary method of fabricating a 1.5 FOWLP structure according to at least one aspect of the disclosure. In FIG. 5A, conductive pillars 230 are formed on a plurality of semiconductor dies 124. In FIG. 5B, the semiconductor dies 124 are separated and placed on a reconstituted or reconfigured (“recon”) wafer 540, which includes a carrier panel 542 and an interface layer 544 between the carrier panel 542 and the semiconductor dies 124.

In FIG. 5C, an encapsulant 120 (e.g., a molding compound) is press-molded onto the semiconductor dies 124 and the recon wafer 540. In FIG. 5D, the encapsulant 120 is back-grinded to expose the top surface of the conductive pillars 230. In FIG. 5E, the insulating layer 118, conductive layer 110, insulating layer 108, and conductive layer 104 (not shown), are formed on the encapsulant 120 using conventional techniques, and the package balls 102 are “dropped” on the conductive layer 106 (not shown). In FIG. 5F, the packages are singulated by a cutter 550.

As can be seen from FIGS. 5A-5F, because the conductive pillars 230 are formed separately from both the semiconductor die 124 and the insulating layer 118, conductive layer 110, insulating layer 108, and conductive layer 104 (not shown), the layout of the conductive pillars 230 can easily be changed. As such, for different package ball layouts, only the layout of the conductive pillars 230 is changed; there is no need to change the layout of the I/O connections of the semiconductor dies 124.

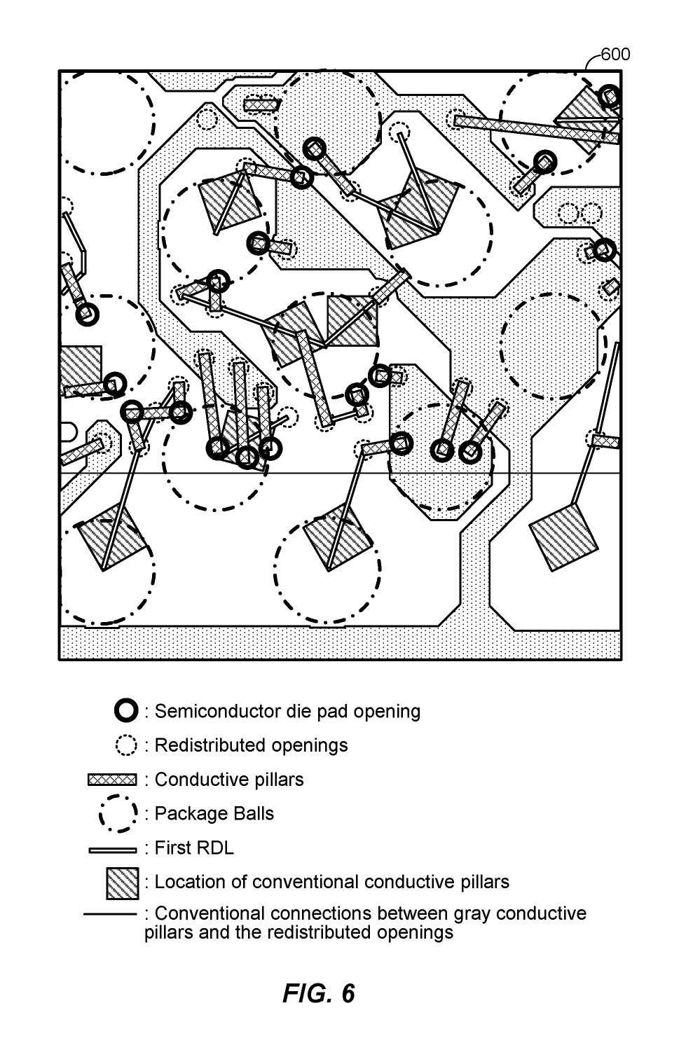

FIG. 6 illustrates a top view of an exemplary 1.5 RDL FOWLP structure 600 according to at least one aspect of the disclosure. In FIG. 6, the blue circles represent semiconductor die openings (e.g., I/O connections formed by conductive layer 126 in FIG. 2), the small black circles represent the redistributed openings (e.g., vias 112 in FIG. 2), the yellow bars represent the conductive pillars (e.g., conductive pillars 230 in FIG. 2), the large circles represent package balls (e.g., package balls 102 in FIG. 2), and the black routing represents the first RDL (e.g., conductive layer 110 in FIG. 2). For reference, the gray boxes in FIG. 6 represent the locations where conventional conductive pillars (e.g., conductive pillars 130 in FIG. 1B) would otherwise be located, and the black lines represent the connections between such conductive pillars and the redistributed openings (e.g., vias 112 in FIG. 1B).

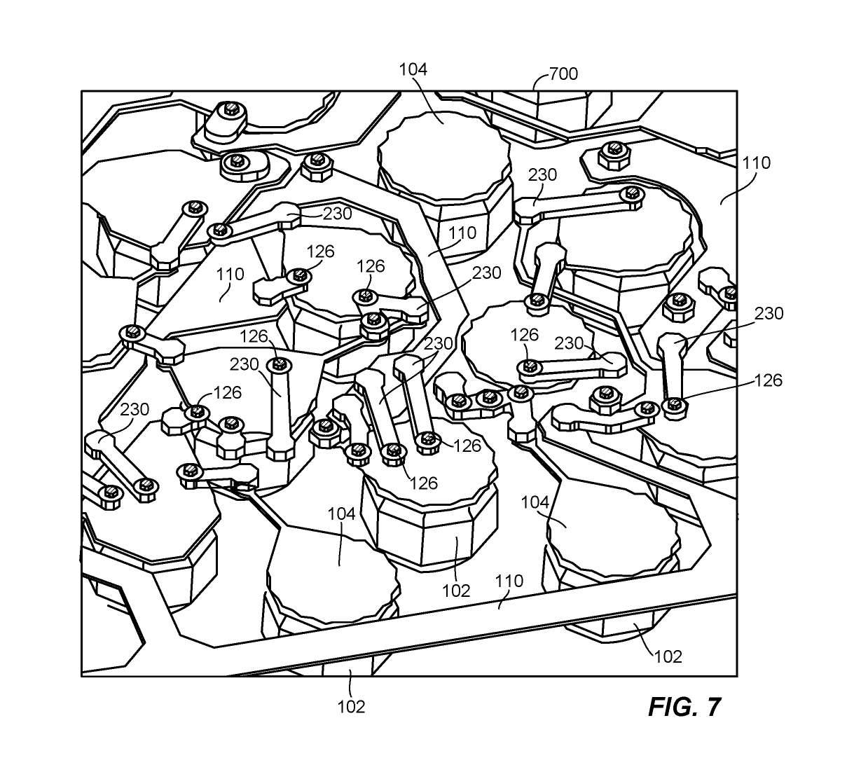

FIG. 7 illustrates a three-dimensional diagram of an exemplary 1.5 RDL FOWLP structure 700 according to at least one aspect of the disclosure. In FIG. 7, various package balls 102, conductive layer 104 (e.g., package ball pads), conductive layers 110 (i.e., the first RDL), conductive pillars 230, and conductive layers 126 (i.e., the I/O connections of a semiconductor die 124 (not shown)) have been labeled. For simplicity and clarity, not all package balls, package ball vias, conductive layers of the first RDL, conductive pillars 230, or semiconductor die I/O connections have been labeled.

As can be seen in FIG. 7, having a width-to-height ratio greater than one allows the conductive pillars 230 to align the conductive layers 126 with the layout of the package balls 102 and the corresponding conductive layers 110 without having to redesign the layout of the conductive layers 126, as would be done if using the conductive pillars 130 of FIG. 1B.

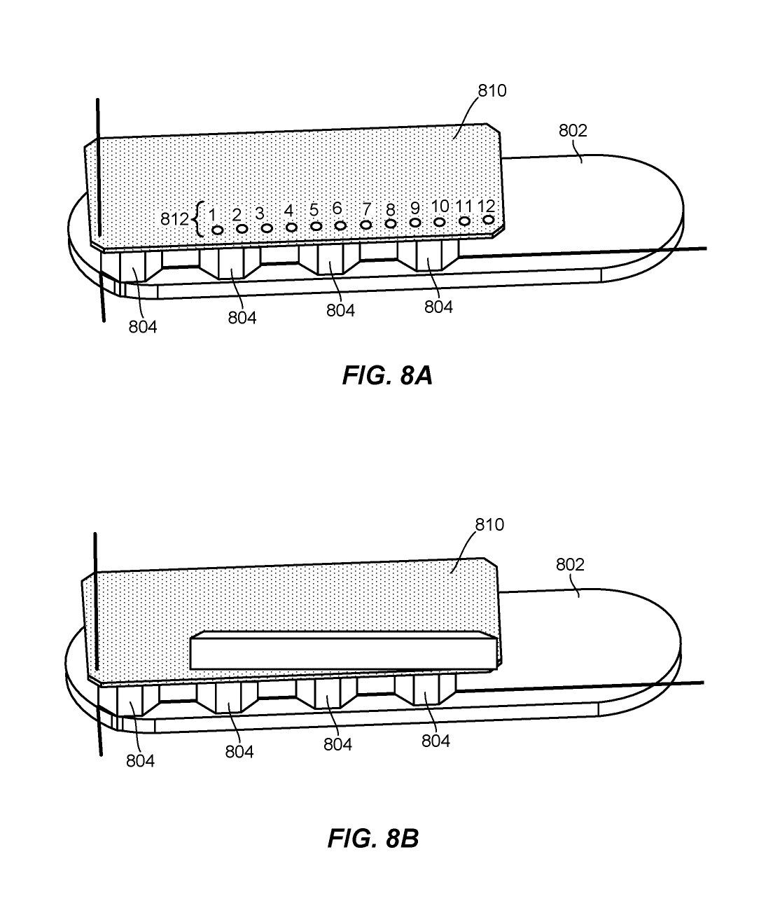

FIG. 8A illustrates an exemplary FOWLP structure for a power management integrated circuit (PMIC) application. In the example of FIG. 8A, a (first) RDL 810 is connected to a printed circuit board (PCB) 802 having a top metal thickness of 70 μm over ball grid array (BGA) 804. The RDL 810 includes twelve PM1 vias 812, although there may be more or less. In FIG. 8A, a PMIC buck regulator has a current rating of 1 A to 4 A. For face-up/conventional FOWLP, PM1 vias 812 in the RDL 810 are used to distribute the current. The simulated current for each via of vias 812 is shown in Table 3. The simulation assumes that all PM1 vias 812 were shorted and the current source provided a 4 A current.

TABLE 3

| | Iₘₐₓ | | | | | | | | | | | |
|---|---|---|---|---|---|---|---|---|---|---|---|---|
| | 1 | 2 | 3 | 4 | 5 | 6 | 7 | 8 | 9 | 10 | 11 | 12 |
| SW(A) | 0.52 | 0.44 | 0.12 | 0.12 | 0.49 | 0.49 | 0.13 | 0.16 | 0.64 | 0.64 | 0.15 | 0.1 |

As can be seen, the currents through vias 1, 9, and 10 are higher than the electromigration (EM) specification (which specifies the maximum current) of 0.5 A.

The design challenge is to balance the current through each via of vias 812. Adding a conductive pillar to the FOWLP structure in FIG. 8A can solve the uneven via current distribution problem. FIG. 8B illustrates an exemplary FOWLP structure for the PMIC application illustrated in FIG. 8A according to at least one aspect of the disclosure. As shown in FIG. 8B, the PM1 vias 812 have been replaced by a conductive pillar 830. The increased contact area provided by the conductive pillar 830 provides a much larger EM current specification. This makes it easier to balance the current. In addition, the IR drop can be reduced.

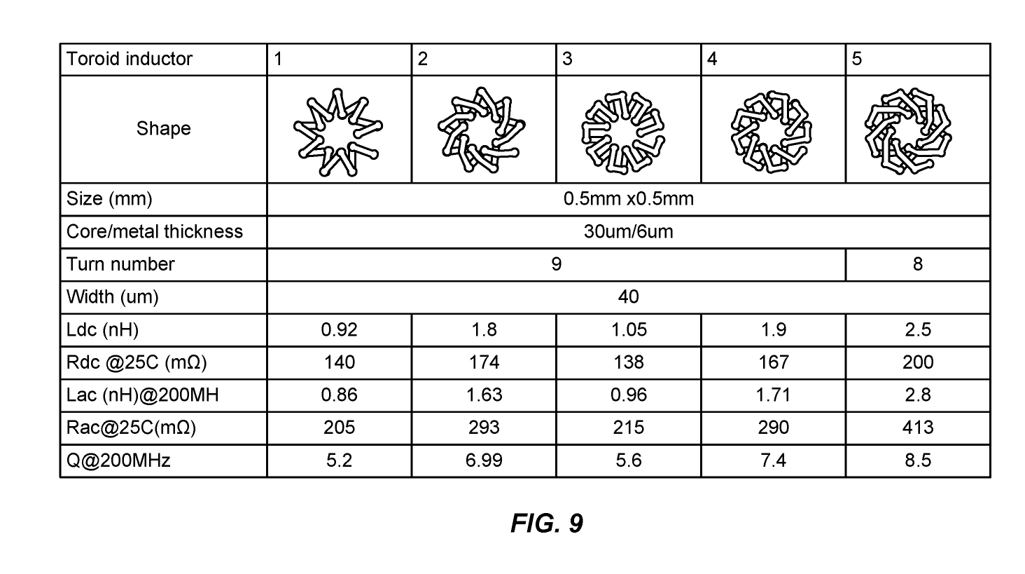

FIG. 9 illustrates how a 1.5 RDL FOWLP structure can be used in a radio frequency (RF) inductor application according to at least one aspect of the disclosure. Specifically, FIG. 9 illustrates several different toroid inductors along with various characteristics. A 1.5 RDL FOWLP structure can also be used as a spiral inductor following the same design principles as a toroid inductor.

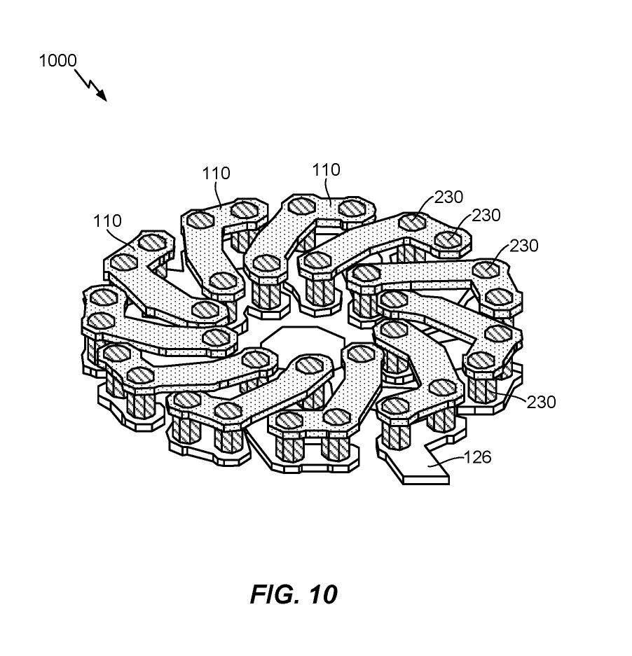

FIG. 10 illustrates a three-dimensional diagram of an exemplary 1.5 RDL FOWLP structure 1000 used as a toroid inductor according to at least one aspect of the disclosure. In FIG. 10, various conductive layers 126 (i.e., semiconductor die I/O connections), conductive layers 110, and conductive pillars 230 have been labeled. For simplicity and clarity, not all conductive pillars, insulating layers, or semiconductor die I/O connections have been labeled.

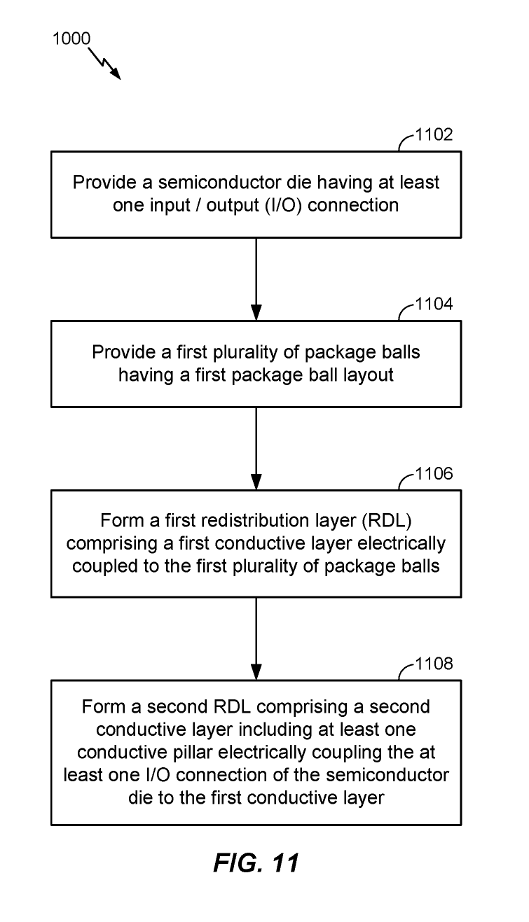

FIG. 11 illustrates an exemplary flow 1100 for manufacturing a 1.5 RDL FOWLP apparatus according to at least one aspect of the disclosure. The flow illustrated in FIG. 11 may be performed by any manufacturing machinery capable of and configured to perform the described operations.

In an embodiment, the apparatus may comprise a toroid inductor, as described above with reference to FIGS. 9 and 10. In an embodiment, the apparatus may comprise a PMIC, and the at least one conductive pillar replaces a plurality of vias of the PMIC.

At 1102, the flow 1100 includes providing a semiconductor die, such as semiconductor die 124 in FIG. 2, having at least one input/output (I/O) connection. At 1104, the flow 1100 includes providing a first plurality of package balls, such as package balls 102 in FIG. 2, having a first package ball layout. At 1106, the flow 1100 includes forming a first redistribution layer (RDL) comprising a first conductive layer, such as the conductive layer 110 (including vias 112) in FIG. 2, electrically coupled to the first plurality of package balls. As used herein, the term “first conductive means” refers to the first conductive layer and equivalents thereof.

At 1108, the flow 1100 includes forming a second RDL comprising a second conductive layer having at least one conductive pillar, such as the conductive pillars 230 in FIG. 2, electrically coupling the at least one I/O connection of the semiconductor die to the first conductive layer. As used herein, the term “second conductive means” refers to the second conductive layer (e.g., the at least one conductive pillar) and equivalents thereof.

The at least one conductive pillar may be formed using a copper pillar plating technology. The second conductive layer enables the semiconductor die to be electrically coupled to a second plurality of package balls having a second package ball layout without a change in position of the at least one I/O connection of the semiconductor die. In an embodiment, the first package ball layout may comprise a package ball layout having a pitch of 0.35 mm, and the second package ball layout may comprise a package ball layout having a pitch of 0.40 mm.

In an embodiment, the at least one conductive pillar may have a width-to-height ratio greater than one. In an embodiment, the width of the at least one conductive pillar may be greater than a height of the at least one conductive pillar. In an embodiment, the width of the at least one conductive pillar may be greater than a height of the at least one conductive pillar. For example, as described herein, the width of the at least one conductive pillar may be 1.5 times the height of the at least one conductive pillar. In an embodiment, the height of the at least one conductive pillar may be within a threshold (e.g., a manufacturing tolerance threshold) d of 30 μm.

In an embodiment, the size and orientation of the at least one conductive pillar may be changed to enable the semiconductor die to be electrically coupled to the second plurality of package balls without the change in position of the at least one I/O connection of the semiconductor die.

There are a number of benefits to the 1.5 RDL FOWLP structure disclosed herein. Because using different package ball layouts does not require a redesign of the semiconductor die I/O connections, there is no cost to tape out different semiconductor die designs for low and high tier market requirements. In addition, 1.5 RDL FOWLP provides lower cost and better board-level reliability (BLR) performance versus traditional multi RDL FOWLP solutions.

Further, the planar surface allows for thinner PM1, which results in finer vias and less topography, which results in finer RDL line width and space (L/S). Further still, 1.5 RDL FOWLP allows for the design of solid current balance and a reduction in the IR drop when using 0.5 RDL. As yet another benefit, 1.5 RDL FOWLP can be used to design inductors when using 0.5 RDL, as described above with reference to FIGS. 9-10.

Note that as used herein, the terms “substantially” and “approximately” are not relative terms of degree, but rather, reflect the reality that, due to tolerances in manufacturing processes, two components may not be exactly the same size or have an exact orientation with respect to each other, or that a given component may not be an exact size. Rather, the terms “substantially” and “approximately” mean that the size, orientation, etc. of the component(s) need only be within some tolerance threshold of the described size, orientation, etc. Thus, for example, when one component is described as being “substantially” above or below another component, it means that the components are aligned vertically within some tolerance threshold. Similarly, as another example, when one component is described as being “approximately” a given size, it means that the component is within a given tolerance threshold of the given size. The tolerance threshold may be determined by the capabilities of the manufacturing process, the requirements of the device and/or components being manufactured, and the like.

It will be appreciated that even if the terms “substantially” or “approximately” are not used to describe a size, orientation, etc. of component(s), it does not mean that the size, orientation, etc. of the component(s) must be exactly the described size, orientation, etc. Rather, the described size, orientation, etc. need only be within some tolerance threshold of the described size, orientation, etc.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

While the foregoing disclosure shows illustrative embodiments of the disclosure, it should be noted that various changes and modifications could be made herein without departing from the scope of the disclosure as defined by the appended claims. The functions, steps and/or actions of the method claims in accordance with the embodiments of the disclosure described herein need not be performed in any particular order. Furthermore, although elements of the disclosure may be described or claimed in the singular, the plural is contemplated unless limitation to the singular is explicitly stated.

What is claimed is:

1. A fan-out wafer level packaging (FOWLP) apparatus, comprising:
a semiconductor die having at least one input/output (I/O) connection;
a first plurality of package balls having a first package ball layout;
a first conductive layer forming a first redistribution layer (RDL) and configured to electrically couple to the first plurality of package balls; and
a second conductive layer forming a second RDL and including at least one conductive pillar configured to electrically couple the at least one I/O connection of the semiconductor die to the first conductive layer,
wherein the second conductive layer enables the semiconductor die to be electrically coupled to a second plurality of package balls having a second package ball layout without a change in position of the at least one I/O connection of the semiconductor die.

2. The apparatus of claim 1, wherein a size and orientation of the at least one conductive pillar is changed to enable the semiconductor die to be electrically coupled to the second plurality of package balls without the change in position of the at least one I/O connection of the semiconductor die.

3. The apparatus of claim 1, wherein the at least one conductive pillar has a width-to-height ratio greater than one.

4. The apparatus of claim 1, wherein a width of the at least one conductive pillar is greater than a height of the at least one conductive pillar.

5. The apparatus of claim 4, wherein the width of the at least one conductive pillar is 1.5 times the height of the at least one conductive pillar.

6. The apparatus of claim 1, wherein a height of the at least one conductive pillar is within a threshold of 30 μm.

7. The apparatus of claim 1, wherein the first package ball layout comprises a package ball layout having a pitch of 0.35 mm, and wherein the second package ball layout comprises a package ball layout having a pitch of 0.40 mm.

8. The apparatus of claim 1, wherein the at least one conductive pillar is formed using a copper pillar plating technology.

9. The apparatus of claim 1, wherein the apparatus comprises a toroid inductor.

10. The apparatus of claim 1, wherein the apparatus comprises a power management integrated circuit (PMIC), and wherein the at least one conductive pillar replaces a plurality of vias of the PMIC.

11. A method of providing a fan-out wafer level packaging (FOWLP) apparatus, comprising:
providing a semiconductor die having at least one input/output (I/O) connection;
providing a first plurality of package balls having a first package ball layout;
forming a first redistribution layer (RDL) comprising a first conductive layer electrically coupled to the first plurality of package balls; and
forming a second RDL comprising a second conductive layer including at least one conductive pillar electrically coupling the at least one I/O connection of the semiconductor die to the first conductive layer,
wherein the second conductive layer enables the semiconductor die to be electrically coupled to a second plurality of package balls having a second package ball layout without a change in position of the at least one I/O connection of the semiconductor die.

12. The method of claim 11, wherein a size and orientation of the at least one conductive pillar is changed to enable the semiconductor die to be electrically coupled to the second plurality of package balls without the change in position of the at least one I/O connection of the semiconductor die.

13. The method of claim 11, wherein the at least one conductive pillar has a width-to-height ratio greater than one.

14. The method of claim 11, wherein a width of the at least one conductive pillar is greater than a height of the at least one conductive pillar.

15. The method of claim 14, wherein the width of the at least one conductive pillar is 1.5 times the height of the at least one conductive pillar.

16. The method of claim 11, wherein a height of the at least one conductive pillar is within a threshold of 30 μm.

17. The method of claim 11, wherein the first package ball layout comprises a package ball layout having a pitch of 0.35 mm, and wherein the second package ball layout comprises a package ball layout having a pitch of 0.40 mm.

18. The method of claim 11, wherein the at least one conductive pillar is formed using a copper pillar plating technology.

19. The method of claim 11, wherein the apparatus comprises a toroid inductor.

20. The method of claim 11, wherein the apparatus comprises a power management integrated circuit (PMIC), and wherein the at least one conductive pillar replaces a plurality of vias of the PMIC.

21. A fan-out wafer level packaging (FOWLP) apparatus, comprising:
a semiconductor die having at least one input/output (I/O) connection;
a first plurality of package balls having a first package ball layout;
a first conductive means forming a first redistribution layer (RDL) and configured to electrically couple to the first plurality of package balls; and
a second conductive means forming a second RDL and including at least one conductive pillar configured to electrically couple the at least one I/O connection of the semiconductor die to the first conductive means,
wherein the second conductive means enables the semiconductor die to be electrically coupled to a second plurality of package balls having a second package ball layout without a change in position of the at least one I/O connection of the semiconductor die.

22. The apparatus of claim 21, wherein a size and orientation of the at least one conductive pillar is changed to enable the semiconductor die to be electrically coupled to the second plurality of package balls without the change in position of the at least one I/O connection of the semiconductor die.

23. The apparatus of claim 21, wherein the at least one conductive pillar has a width-to-height ratio greater than one.

24. The apparatus of claim 21, wherein a width of the at least one conductive pillar is greater than a height of the at least one conductive pillar.

25. The apparatus of claim 24, wherein the width of the at least one conductive pillar is 1.5 times the height of the at least one conductive pillar.

26. The apparatus of claim 21, wherein a height of the at least one conductive pillar is within a threshold of 30 μm.

27. The apparatus of claim 21, wherein the first package ball layout comprises a package ball layout having a pitch of 0.35 mm, and wherein the second package ball layout comprises a package ball layout having a pitch of 0.40 mm.

28. The apparatus of claim 21, wherein the apparatus comprises a toroid inductor.

29. The apparatus of claim 21, wherein the apparatus comprises a power management integrated circuit (PMIC), and wherein the at least one conductive pillar replaces a plurality of vias of the PMIC.

30. A non-transitory computer-readable medium storing computer executable code, comprising code to:
cause a machine to provide a semiconductor die having at least one input/output (I/O) connection;
cause a machine to provide a first plurality of package balls having a first package ball layout;
cause a machine to form a first redistribution layer (RDL) comprising a first conductive layer configured to electrically couple to the first plurality of package balls; and
cause a machine to form a second RDL comprising a second conductive layer including at least one conductive pillar configured to electrically couple the at least one I/O connection of the semiconductor die to the first conductive layer,
wherein the second conductive layer enables the semiconductor die to be electrically coupled to a second plurality of package balls having a second package ball layout without a change in position of the at least one I/O connection of the semiconductor die.
